(19) United States
(12) Patent Application Publication
(10) Pub. No.: US 2025/0105162 A1
(43) Pub. Date: Mar. 27, 2025

(54) Semiconductor Device and Method of Forming Fine-Pitch Interconnection Using Insulating Layer

(71) Applicant: JCET STATS ChipPAC Korea Limited, Incheon (KR)

(72) Inventors: SeungHyun Lee, Incheon (KR); HunTeak Lee, Gyeonggi-do (KR); SangHoon Lee, Incheon (KR); HeeSoo Lee, Incheon (KR)

(73) Assignee: JCET STATS ChipPAC Korea Limited, Incheon (KR)

(21) Appl. No.: 18/471,960

(22) Filed: Sep. 21, 2023

(51) Int. Cl. H01L 23/538; H01L 21/48; H01L 23/00; H01L 25/10

(52) U.S. Cl. CPC H01L 23/5386; H01L 21/4857; H01L 23/5383; H01L 24/16; H01L 24/81; H01L 25/105; H01L 2224/16227; H01L 2224/81815

(57) ABSTRACT

A semiconductor device has an interconnect substrate and a plurality of conductive pads formed over a first surface of the interconnect substrate. The conductive pads have a fine pitch. An insulating layer is formed over the conductive pads. The insulating layer is formed over a side surface and a top surface of the conductive pads. An electrical component is disposed over the first surface of the interconnect substrate. The electrical component has an interconnect structure making electrical connection to the conductive pads through the insulating layer while leaving a portion of the insulating layer over a side surface of the interconnect structure. The interconnect structure breaks through the insulating layer under force and pressure by TCB to leave the portion of the insulating layer over the side surface of the interconnect structure to avoid an electrical short between the conductive pads.

### FIELD OF THE INVENTION

The present invention relates in general to semiconductor devices and, more particularly, to a semiconductor device and method of forming a fine-pitch interconnection using an insulating layer formed over conductive pads.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

A semiconductor wafer typically contains a plurality of semiconductor die separated by a saw street. The semiconductor wafer is singulated into a plurality of individual semiconductor die. A semiconductor package may contain a semiconductor die mounted to an interconnect substrate. The electrical interconnect between the semiconductor die and interconnect substrate may have a fine pitch to maximize interconnectivity. The fine-pitch electrical interconnects, typically bumps or bumps on pads, are subject to electrical shorting or bride failure, particularly during the bonding process. The fine-pitch electrical interconnects can also be left as an open circuit. Both scenarios are undesirable and lead to product defects, lower yield, and high manufacturing costs.

### BRIEF DESCRIPTION OF THE DRAWINGS

FIGS. 1a-1f illustrate a semiconductor wafer with a plurality of semiconductor die separated by a saw street;

FIGS. 2a-2i illustrate a process of forming an interconnect structure with fine-pitch conductive pads covered by an insulating layer;

FIGS. 3a-3d illustrate disposing an electrical component on the conductive pads of the interconnect structure and breaking through the insulating layer to make electrical connection without electrical shorts;

FIG. 4 illustrates forming bump over the interconnect substrate opposite the electrical component;

FIGS. 5a-5b illustrate disposing an electrical component on the conductive pads of the interconnect structure and breaking through the insulating layer to make electrical connection without electrical shorts; and

FIG. 6 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

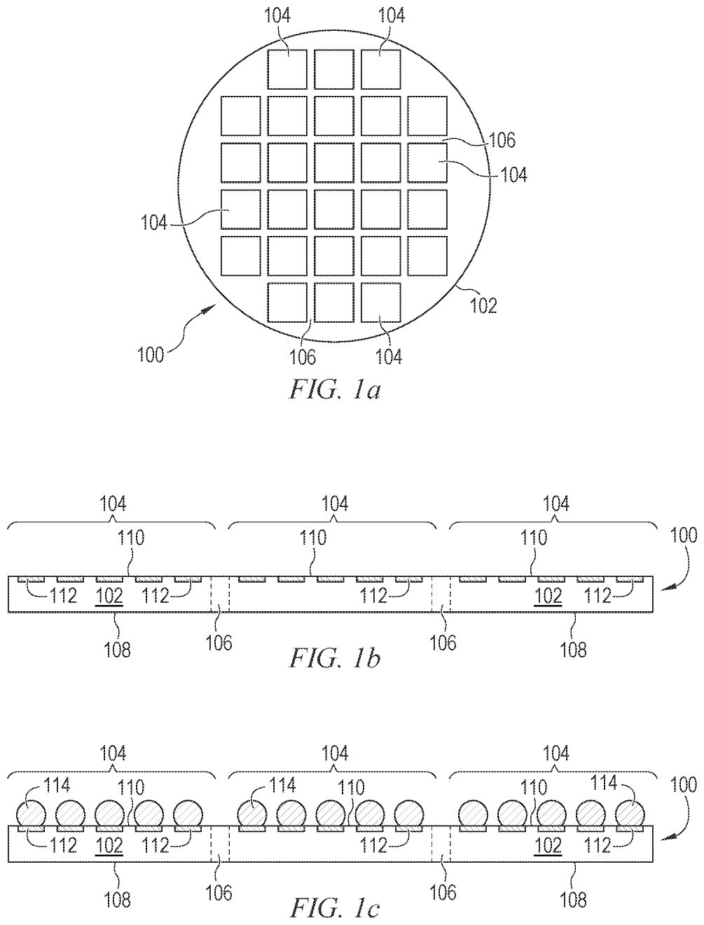

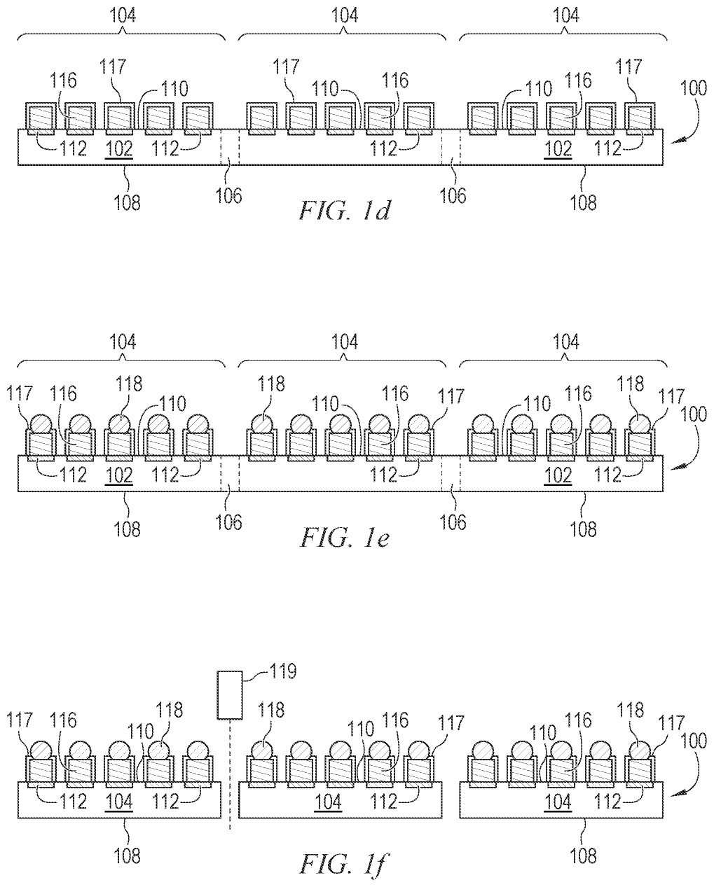

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain integrated passive devices (IPD), such as inductors, capacitors, and resistors, for RF signal processing.

An electrically conductive layer 112 is formed over active surface 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

In FIG. 1c, an electrically conductive bump material is deposited over conductive layer 112 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. Bump 114 can be formed over an under bump metallization (UBM) having a wetting layer, barrier layer, and adhesive layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

In another embodiment, continuing from FIG. 1b, a plurality of conductive pads 116 are formed over conductive layer 112, as shown in FIG. 1d. Conductive pads 116 can be considered as conductive columns or pillars or posts. To form conductive pads 116, a solder resist or photoresist layer (not shown) is formed over active surface 110. A plurality of openings is formed in the solder resist/photoresist using an etching process or laser direct ablation (LDA) to define a pattern to form the conductive pads. The openings are filled with conductive material and the remaining solder resist/photoresist is removed leaving conductive pads 116. Conductive columns or pad 116 can be Al, Cu, Sn, Ni, Au, Ag, multi-layer combined or other suitable electrically conductive material. Conductive pads 116 can have a height of less than 5.0 μm to compensate for thickness variation in different technologies, such as surface mount and flipchip. In one embodiment, conductive pads 116 may have an optional Cu organic solderability preservative (OSP), or electroless-nickel electroless-palladium immersion gold (ENEPIG), or electroless nickel immersion gold (ENIG), or immerging tin, or solder cap finish or layer 117 formed on exposed metal surfaces.

In FIG. 1e, an electrically conductive bump material is deposited over conductive pad 116 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive pad 116 using a suitable attachment or bonding process. In one embodiment, the bump material is reflowed by heating the material above its melting point to form balls or bumps 118. Bump 118 can also be compression bonded or thermocompression bonded to conductive pad 116. Bump 118 represents one type of interconnect structure that can be formed over conductive pad 116. The interconnect structure can also use bond wires, conductive paste, stud bump, micro bump, or other electrical interconnect.

In FIG. 1f, semiconductor wafer 100 from FIG. 1c or FIG. 1e is singulated through saw street 106 using a saw blade or laser cutting tool 119 into individual semiconductor die 104. The individual semiconductor die 104 can be inspected and electrically tested for identification of known good die or unit (KGD/KGU) post singulation.

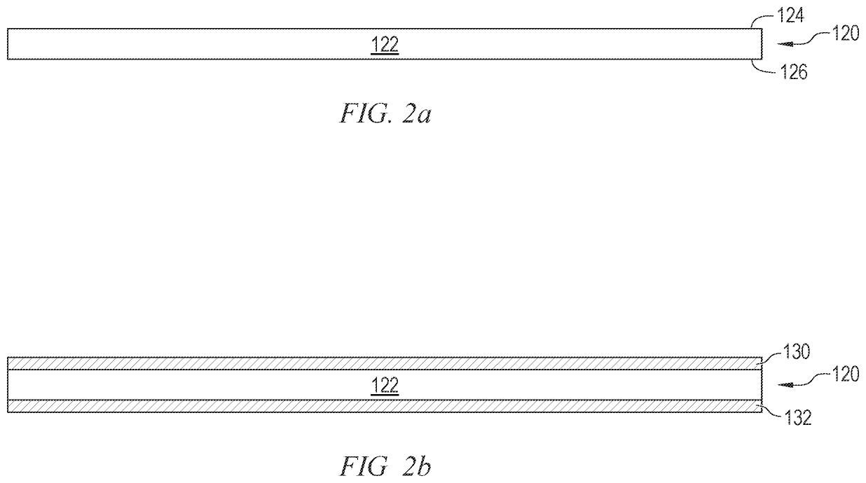

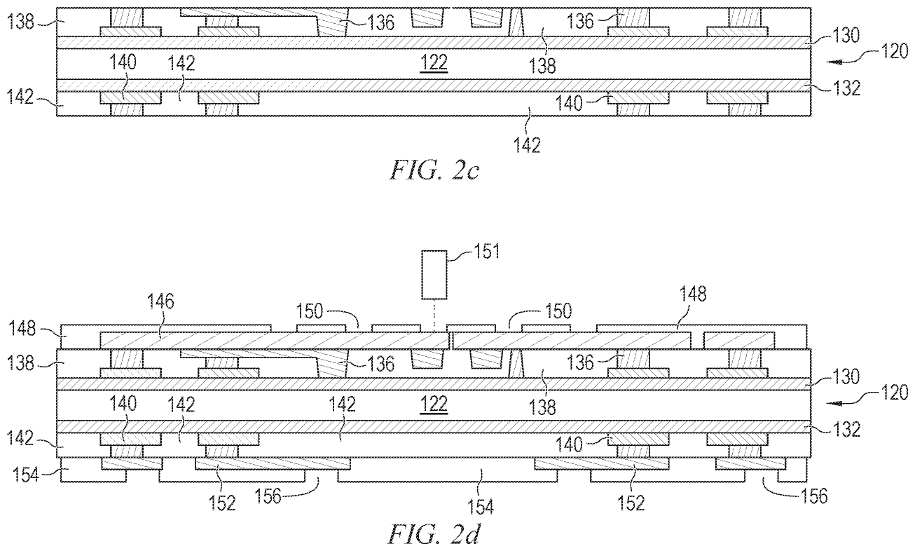

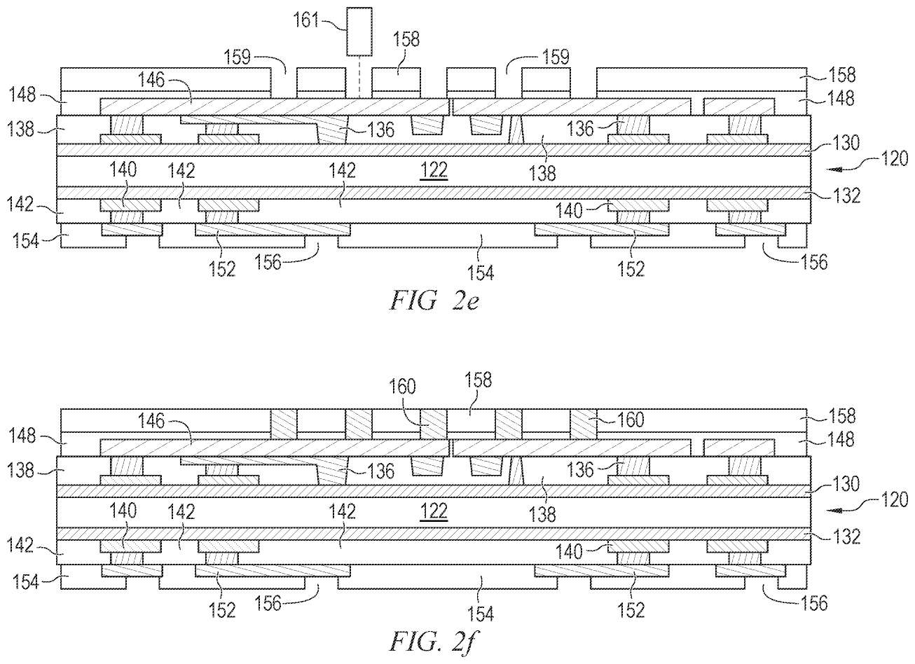

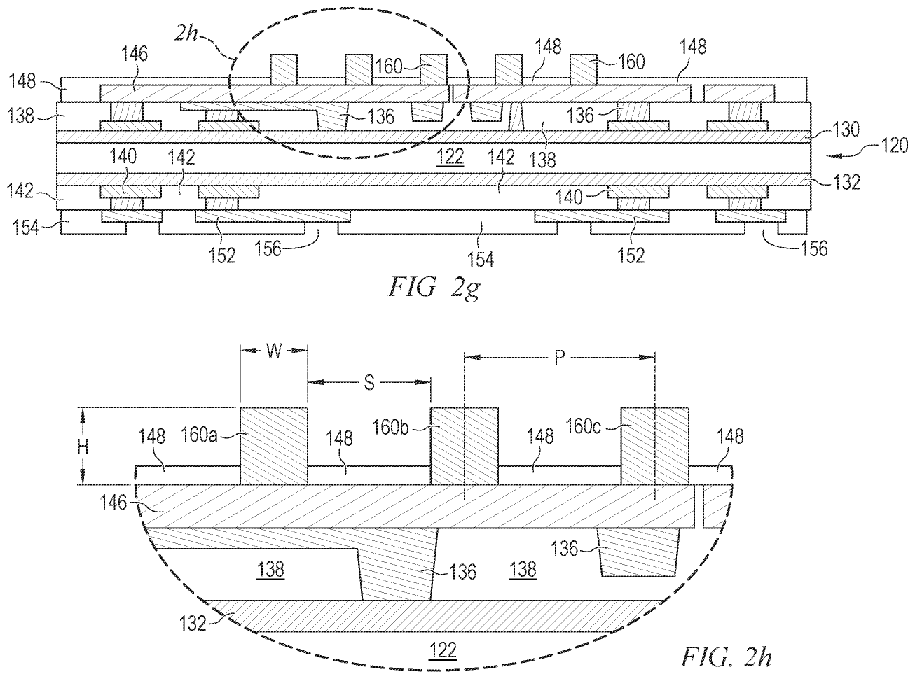

FIGS. 2a-2i illustrate a process of forming a double-sided interconnect substrate. FIG. 2a shows a core substrate 120 made with base material 122 as a multi-layer flexible laminate, ceramic, copper clad laminate (CCL), glass, or epoxy molding compound. Base material 122 can contain one or more layers of SiO2, Si3N4, SiON, Ta2O5, Al2O3, solder resist, polyimide, BCB, PBO, and other material having similar insulating and structural properties. Core substrate 120 may include one or more laminated layers of polytetrafluoroethylene (PTFE) pre-impregnated (prepreg), FR-4, FR-1, CEM-1, or CEM-3 with a combination of phenolic cotton paper, epoxy, resin, woven glass, matte glass, polyester, and other reinforcement fibers or fabrics. In another embodiment, core substrate 120 can also be any suitable laminate interposer, PCB, wafer-form, strip interposer, leadframe, or other type of substrate. Core substrate 120 has a thickness of 150.0 micrometers (μm) and includes first major surface 124 and second major surface 126 opposite surface 124.

In FIG. 2b, electrically conductive layer 130 is formed on surface 124, and electrically conductive layer 132 is formed on surface 126. Conductive layers 130 and 132 can be formed using PVD, CVD, electrolytic plating, electroless plating process, or other suitable metal deposition process. Conductive layers 130 and 132 can be one or more layers of Al, Cu, Sn, Ni, Au, Ag, or other suitable electrically conductive material. The combination of core substrate 120 and conductive layers 130 and 132 constitute copper core laminate (CCL) substrate.

In FIG. 2c, electrically conductive layer 136 is formed over conductive layer 130, and insulating layer 138 is formed over and around conductive layer 136. In a similar manner, electrically conductive layer 140 is formed over conductive layer 132, and insulating layer 142 is formed over and around conductive layer 140. Conductive layers 136 and 140 can be formed using PVD, CVD, electrolytic plating, electroless plating process, or other suitable metal deposition process. Conductive layers 136 and 140 can be one or more layers of Al, Cu, Sn, Ni, Au, Ag, or other suitable electrically conductive material. Conductive layers 136 and 140 can be patterned and etched to form a circuit layout, i.e., with conductive traces routed to provide electrical function. Alternatively, the circuit layout can be formed by LDA. Insulating layers 138 and 142 contain one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Insulating layers 138 and 142 can be formed using PVD, CVD, printing, lamination, spin coating, spray coating, sintering, or thermal oxidation. Insulating layers 138 and 142 provide isolation between conductive layers 136 and 140, respectively. There can be multiple conductive layers like 136 and 140 separated by multiple insulating layers like 138 and 142.

In FIG. 2d, electrically conductive layer 146 is formed over conductive layer 136, and insulating layer 148 is formed over and around conductive layer 146. A plurality of openings 150 is formed in insulating layer 148 using an etching process or LDA with laser 151. Openings 150 extend to conductive layer 146. In a similar manner, electrically conductive layer 152 is formed over conductive layer 140, and insulating layer 154 is formed over and around conductive layer 152. A plurality of openings 156 is formed in insulating layer 154 using an etching process or LDA. Openings 156 extend to conductive layer 152. Conductive layers 146 and 152 can be formed using PVD, CVD, electrolytic plating, electroless plating process, or other suitable metal deposition process. Conductive layers 146 and 152 can be one or more layers of Al, Cu, Sn, Ni, Au, Ag, or other suitable electrically conductive material. Conductive layers 146 and 152 can be patterned and etched to form a circuit layout, i.e., with conductive traces routed to provide electrical function. Alternatively, the circuit layout can be formed by LDA. Portions of conducive layers 136, 140, 146, and 152 can be electrically common or electrically isolated depending on the design and function of later added electrical components. Insulating layers 148 and 154 contain one or more layers of SiO2, Si3N4, SiON, Ta2O5, Al2O3, solder resist, polyimide, BCB, PBO, and other material having similar insulating and structural properties. Insulating layers 148 and 154 can be formed using PVD, CVD, printing, lamination, spin coating, spray coating, sintering, or thermal oxidation. Insulating layers 148 and 154 provide isolation between conductive layers 146 and 152, respectively. There can be multiple conductive layers like 146 and 152 separated by multiple insulating layers like 148 and 154.

In FIG. 2e, solder resist or photoresist layer 158 is formed over insulating layer 148 and conductive layer 146. A plurality of openings 159 is formed in solder resist/photoresist 158 using an etching process or LDA using laser 161 to define a pattern to form the conductive pads.

In FIG. 2f, openings 159 are filled with conductive material and the remaining solder resist/photoresist is removed leaving conductive pads 160, as in FIG. 2g. Conductive pads 160 can be Al, Cu, Sn, Ni, Au, Ag, multi-layer combined or other suitable electrically conductive material. Conductive pads 160 can be considered as conductive columns or pillars or posts.

FIG. 2h shows further detail of conductive pads 160a, 160b, and 160c formed over conductive layer 146. Conductive pads 160 have a fine pitch P of 10-30 μm and spacing S between pads of 5-25 μm. Conductive pads 160 have a width W of 5-20 μm and height H of 10-50 μm to compensate for thickness variation in different technologies, such as surface mount and flipchip.

In FIG. 2i, insulating layer 164 is formed over conductive pad 160, including side surface 166 of the conductive pad. Insulating layer 164 contains one or more layers of SiO2, Si3N4, SiON, Ta2O5, Al2O3, solder resist, polyimide, BCB, PBO, and other material having similar insulating and structural properties. Insulating layer 164 can be formed using PVD, CVD, printing, lamination, spin coating, spray coating, sintering, or thermal oxidation. Insulating layer 164 is a nano-thickness coating protecting conductive pads 160 from oxidation. In one embodiment, insulting layer 164 is SiO2 with a nano-thickness of 50-150 nanometers (nm). The nano-coating is capable of being broken through to protect the electrical interconnect process, as discussed infra.

The combination of core substrate 120, conductive layers 130, 132, 136, 140, and 146, insulating layers 138, 142, 148, and 154, and conductive pads 160, and insulating layer 164 constitute interconnect substrate 170.

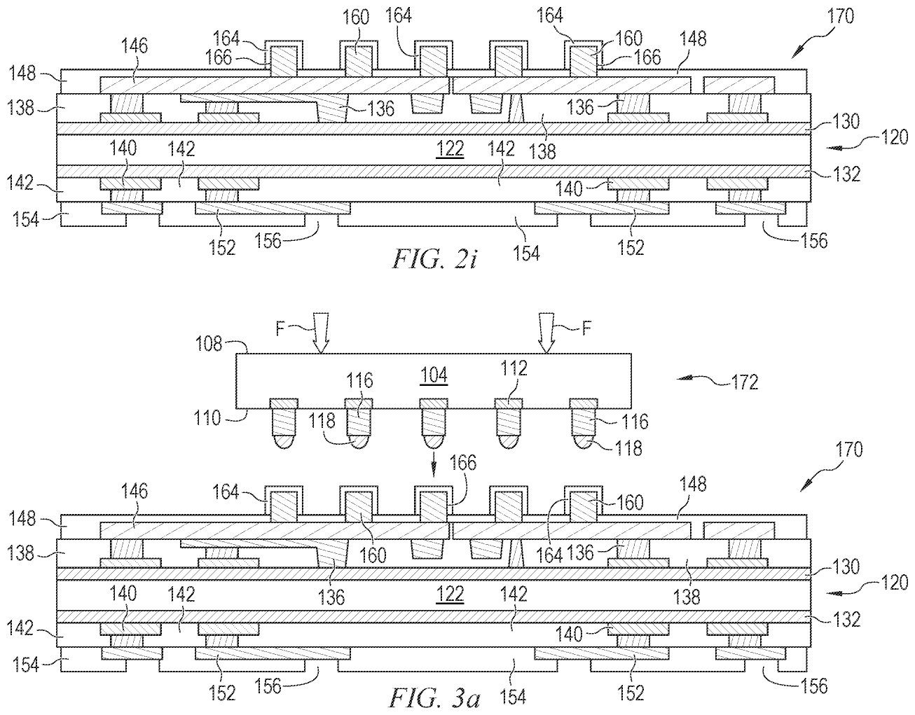

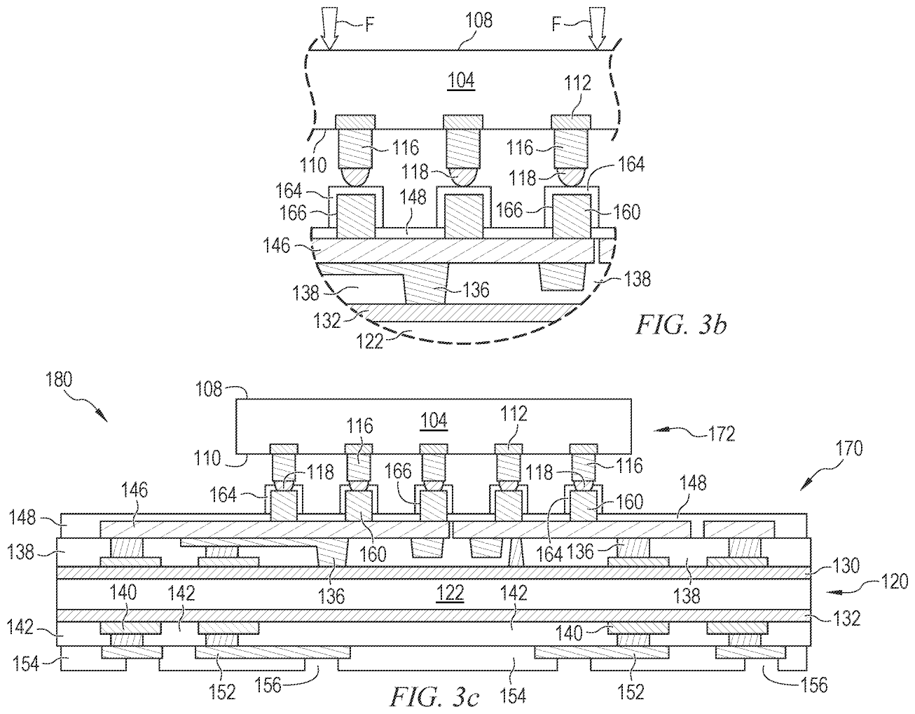

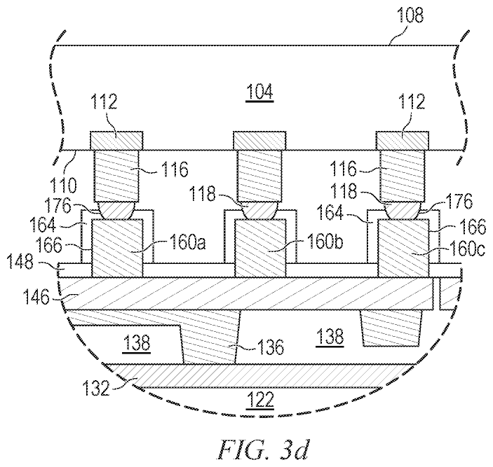

In FIG. 3a, one or more electrical components 172 are disposed over interconnect substrate 170 and electrically and mechanically connected to conductive pads 160. For example, electrical component 172 can be similar to, or made similar to, semiconductor die 104 from FIG. 1f with conductive pads 116 and bumps 118 oriented toward conductive pads 160, in this case without finish 117. In another embodiment, electrical component 172 can be semiconductor die 104 from FIG. 1c with bumps 114 oriented toward conductive pads 160. Electrical component 172 can be other semiconductor die, semiconductor packages, surface mount devices, RF components, discrete electrical devices, or IPD.

Electrical component 172 is positioned over interconnect substrate 170 using a pick and place operation. FIG. 3b shows bumps 118 of electrical component 170 is brought into contact with insulating layer 164 of interconnect substrate 170. Under force F applied to back surface 108, bumps 118 of electrical component 170 are driven through insulating layer 164 using thermal compression bonding (TCB) and electrically and mechanically connected to conductive pad 160, as shown in FIG. 3c. TCB has sufficient pressure and force to push bump 118 through insulating layer 164, breaking through the portion of the insulating layer over conductive pad 160 by compressive force and making physical contact with the conductive pad. Bumps 118 can also be reflowed to make mechanical and electrical connection to conductive pads 160.

FIG. 3d shows bump 118, after TCB and/or reflow, having been driven through insulating layer 164 to make electrical and mechanical connection to conductive pad 160. Notice that with bump 118 being driven through insulating layer 164, the insulating layer now surrounds at least a portion of the bump. That is, insulating layer 164 now covers side surface 176 of bump 118, as well as side surfaces 166 of conductive pads 160. Given the fine pitch of conductive pads 160 and 116, insulating layer 164 provides electrical isolation and protection from shorting between the interconnect structures, particularly during reflow of bumps 118. FIG. 3d shows no unintended electrical connection between conductive pads 160a and 160b, or between conductive pads 160b and 160c, following the TCB or reflow process, due in part to insulating layer 164 providing electrical isolation between the fine-pitch structures.

The combination of electrical component 170 disposed on interconnect substrate 170 with bumps 118 bonded to conductive pads 160 constitutes semiconductor package 180. Semiconductor package 180 with fine-pitch bumps 118 and fine-pitch conductive pads 160 avoids undesired electrical shorts with the electrical isolation of insulating layer 164. Insulating layer 164 increases component yield and lowers manufacturing costs.

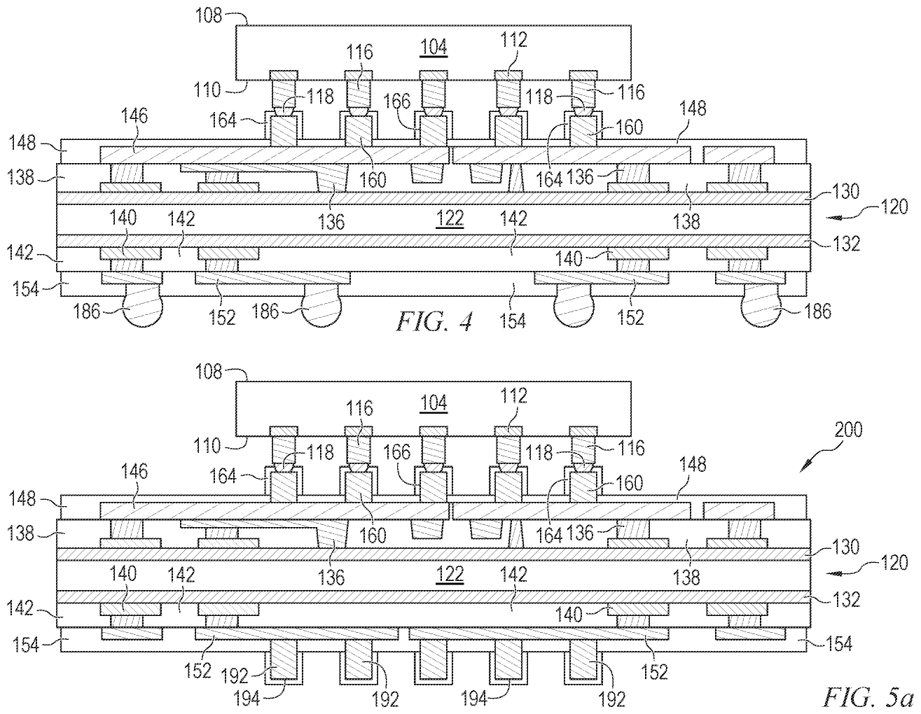

In FIG. 4, an electrically conductive bump material is deposited over conductive layer 152 of interconnect substrate 170 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 152 using a suitable attachment or bonding process. In one embodiment, the bump material is reflowed by heating the material above its melting point to form balls or bumps 186. Bump 186 can be formed over a UBM having a wetting layer, barrier layer, and adhesive layer. Bump 186 can also be compression bonded or thermocompression bonded to conductive layer 152. Bump 186 represents one type of interconnect structure that can be formed over conductive layer 152. The interconnect structure can also use bond wires, conductive paste, stud bump, micro bump, or other electrical interconnect.

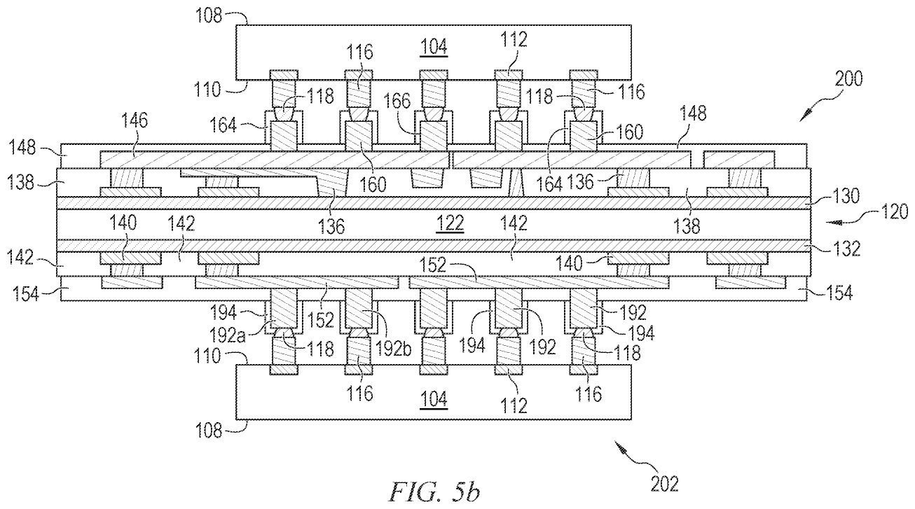

FIG. 5a illustrates an embodiment with conductive pads 190 formed over conductive layer 152, similar to FIGS. 2e-2h. Elements having a similar function are assigned the same reference number. An insulating layer 194 is formed over conductive pad 190, similar to FIG. 2i. The combination of core substrate 120, conductive layers 130, 132, 136, 140, and 146, insulating layers 138, 142, 148, and 154, and conductive pads 190, and insulating layer 194 constitute interconnect substrate 200.

In FIG. 5b, one or more electrical components 202 are disposed over interconnect substrate 200 and electrically and mechanically connected to conductive pads 192, similar to FIGS. 3a-3b. For example, electrical component 202 can be similar to, or made similar to, semiconductor die 104 from FIG. 1f with conductive pads 116 and bumps 118 oriented toward conductive pads 192. Conductive pads 192 can be considered as conductive columns or pillars or posts. In another embodiment, electrical component 202 can be semiconductor die 104 from FIG. 1c with bumps 114 oriented toward conductive pads 192. Electrical component 202 can be other semiconductor die, semiconductor packages, surface mount devices, RF components, discrete electrical devices, or IPD.

Under force F applied to back surface 108, bumps 118 of electrical component 202 is driven through insulating layer 194 using TCB and electrically and mechanically connected to conductive pad 192, similar to FIGS. 3c-3d. TCB has sufficient pressure and force to push bump 118 through insulating layer 194, breaking through the portion of the insulating layer over conductive pad 190 by compressive force and making physical contact with conductive pad 192. Bumps 118 can also be reflowed to make mechanical and electrical connection to conductive pads 192. In any case, there is no unintended electrical connection between conductive pad 192a and 192b, due in part to insulating layer 194 providing electrical isolation between the structures.

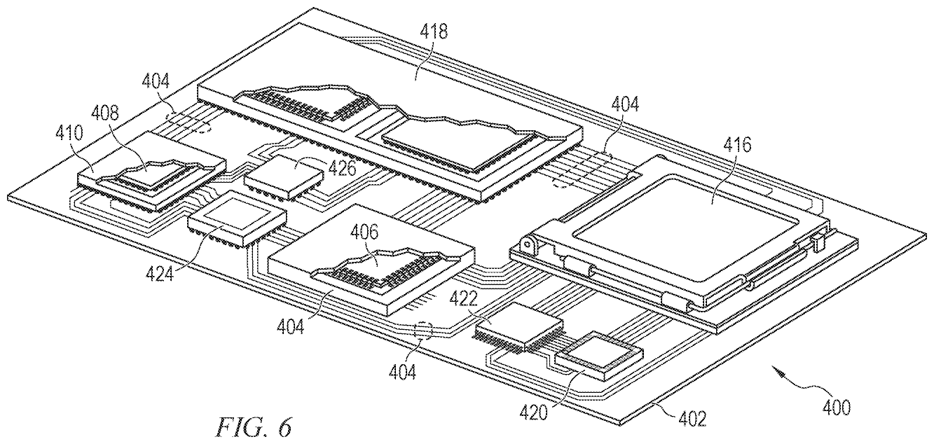

FIG. 6 illustrates electrical device 400 having a chip carrier substrate or PCB 402 with a plurality of semiconductor packages disposed on a surface of PCB 402, including semiconductor package 180. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 6, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
an interconnect substrate;
a plurality of first conductive pads formed over a first surface of the interconnect substrate;
a first insulating layer formed over the first conductive pads; and
a first electrical component disposed over the first surface of the interconnect substrate, wherein the first electrical component includes an interconnect structure making electrical connection to the first conductive pads through the first insulating layer while leaving a portion of the first insulating layer over a side surface of the interconnect structure.

2. The semiconductor device of claim 1, wherein the first conductive pads include a fine pitch.

3. The semiconductor device of claim 1, wherein the first insulating layer is formed over a side surface and a top surface of the first conductive pads.

4. The semiconductor device of claim 1, wherein the interconnect substrate includes:
a core substrate;
a first conductive layer formed over a first surface of the core substrate; and
a first insulating layer formed over the first conductive layer.

5. The semiconductor device of claim 4, wherein the interconnect substrate includes:
a second conductive layer formed over a second surface of the core substrate opposite the first surface of the core substrate; and
a second insulating layer formed over the second conductive layer.

6. The semiconductor device of claim 1, further including:
a plurality of second conductive pads formed over a second surface of the interconnect substrate;
a second insulating layer formed over the second conductive pads; and
a second electrical component disposed over the second surface of the interconnect substrate and making electrical connection to the second conductive pads through the second insulating layer.

7. A semiconductor device, comprising:
an interconnect substrate;
a plurality of first conductive pads formed over a first surface of the interconnect substrate;
a first insulating layer formed over the first conductive pads; and
a first electrical component disposed over the first surface of the interconnect substrate and making electrical connection to the first conductive pads through the first insulating layer.

8. The semiconductor device of claim 7, wherein the first conductive pads include a fine pitch.

9. The semiconductor device of claim 7, wherein the first insulating layer is formed over a side surface and a top surface of the first conductive pads.

10. The semiconductor device of claim 7, wherein the interconnect substrate includes:
a core substrate;
a first conductive layer formed over a first surface of the core substrate; and
a first insulating layer formed over the first conductive layer.

11. The semiconductor device of claim 10, wherein the interconnect substrate includes:
a second conductive layer formed over a second surface of the core substrate opposite the first surface of the core substrate; and
a second insulating layer formed over the second conductive layer.

12. The semiconductor device of claim 11, further including a bump formed over the second conductive layer.

13. The semiconductor device of claim 7, further including:
a plurality of second conductive pads formed over a second surface of the interconnect substrate;
a second insulating layer formed over the second conductive pads; and
a second electrical component disposed over the second surface of the interconnect substrate and making electrical connection to the second conductive pads through the second insulating layer.

14. A method of making a semiconductor device, comprising:
providing an interconnect substrate;
forming a plurality of first conductive pads over a first surface of the interconnect substrate;
forming a first insulating layer over the first conductive pads; and
disposing a first electrical component over the first surface of the interconnect substrate, wherein the first electrical component includes an interconnect structure making electrical connection to the first conductive pads through the first insulating layer while leaving a portion of the first insulating layer over a side surface of the interconnect structure.

15. The method of claim 14, wherein the first conductive pads include a fine pitch.

16. The method of claim 14, further including forming the first insulating layer over a side surface and a top surface of the first conductive pads.

17. The method of claim 14, wherein providing the interconnect substrate includes:
providing a core substrate;
forming a first conductive layer over a first surface of the core substrate; and
forming a first insulating layer over the first conductive layer.

18. The method of claim 17, wherein providing the interconnect substrate further includes:
forming a second conductive layer over a second surface of the core substrate opposite the first surface of the core substrate; and
forming a second insulating layer over the second conductive layer.

19. The method of claim 14, further including:
forming a plurality of second conductive pads over a second surface of the interconnect substrate;
forming a second insulating layer over the second conductive pads; and
disposing a second electrical component over the second surface of the interconnect substrate and making electrical connection to the second conductive pads through the second insulating layer.

20. A method of making a semiconductor device, comprising:
providing an interconnect substrate;
forming a plurality of first conductive pads over a first surface of the interconnect substrate;
forming a first insulating layer over the first conductive pads; and
disposing a first electrical component over the first surface of the interconnect substrate and making electrical connection to the first conductive pads through the first insulating layer.

21. The method of claim 20, wherein the first conductive pads include a fine pitch.

22. The method of claim 20, further including forming the first insulating layer is formed over a side surface and a top surface of the first conductive pads.

23. The method of claim 20, wherein providing the interconnect substrate includes:
providing a core substrate;
forming a first conductive layer over a first surface of the core substrate; and
forming a first insulating layer over the first conductive layer.

24. The method of claim 23, wherein providing the interconnect substrate further includes:
forming a second conductive layer over a second surface of the core substrate opposite the first surface of the core substrate; and
forming a second insulating layer over the second conductive layer.

25. The method of claim 20, further including:
forming a plurality of second conductive pads over a second surface of the interconnect substrate;
forming a second insulating layer over the second conductive pads; and
disposing a second electrical component over the second surface of the interconnect substrate and making electrical connection to the second conductive pads through the second insulating layer.
